(19) United States
(12) Patent Application Publication
(10) Pub. No.: US 2018/0188427 A1
(43) Pub. Date: Jul. 5, 2018

(54) Color Filter Array for Image Capture Device

(71) Applicant: Uber Technologies, Inc., San Francisco, CA (US)

(72) Inventors: Peter G. Brueckner, Pittsburgh, PA (US); Carl Knox Wellington, Pittsburgh, PA (US); David C. Driscoll, Pittsburgh, PA (US)

(21) Appl. No.: 15/850,452

(22) Filed: Dec. 21, 2017

Related U.S. Application Data
(60) Provisional application No. 62/439,910, filed on Dec. 29, 2016.

(51) Int. Cl. G02B 5/20; H04N 9/04; H01L 27/146

(52) U.S. Cl. CPC G02B 5/201; H01L 27/14645; H01L 27/14621; H04N 9/045

(57) ABSTRACT

Image capture devices can include an image sensor, a color filter array, and an image processor. The image sensor can include an array of sensor elements configured to detect incoming light provided incident to a surface of the image sensor. The color filter array can be positioned adjacent to the image sensor for filtering the incoming light provided incident to the surface of the image sensor. The color filter array can include an array of filter elements including a plurality of clear filter elements and a plurality of color-sensitive filter elements. The plurality of color-sensitive filter elements can include at least one first color-sensitive filter element sensitive to a first band of the visible color spectrum and at least one second color-sensitive filter element sensitive to a second band of the visible color spectrum different than the first band.

### PRIORITY CLAIM

The present application is based on and claims benefit of U.S. Provisional Application 62/439,910 having a filing date of Dec. 29, 2016, which is incorporated by reference herein.

### FIELD

The present disclosure relates generally to an image capture device, and more particularly to an image capture device and image processing system that includes a color filter array.

### BACKGROUND

Sensors are increasingly used in vehicle applications to help provide useful information associated with vehicle operation. For example, image sensors found in cameras or other image capture devices can be used to capture images of an operating environment surrounding a vehicle. In autonomous vehicles, cameras and other sensors can be used to help determine vehicle position from sensor data identifying various aspects of the vehicle's surroundings. Cameras capable of obtaining color images can be especially useful for specific applications involving image classification and/or scene interpretation. In addition, cameras that provide global shutter exposure are very useful for sensor fusion with other sensing modalities and provide distortion-free imagery of moving objects that cannot be achieved with an electronic rolling shutter (ERS) sensor. Global shutter sensor cameras, however, typically have worse low-light performance than ERS sensor cameras. Low light conditions can sometimes be encountered during the wide variety of operating conditions encountered by a vehicle camera, especially at night. For example, fluctuating amounts of ambient light can be available at different times of day, in various weather conditions, and in varied navigational surroundings of a vehicle. All of these competing design requirements result in a camera design that can be challenging to produce.

### SUMMARY

Aspects and advantages of embodiments of the present disclosure will be set forth in part in the following description, or may be learned from the description, or may be learned through practice of the embodiments.

One example aspect of the present disclosure is directed to an image capture device. The image capture device includes an image sensor, a color filter array, and an image processor. The image sensor includes an array of sensor elements configured to detect incoming light provided incident to a surface of the image sensor. The color filter array is positioned adjacent to the image sensor for filtering the incoming light provided incident to the surface of the image sensor. The color filter array includes an array of filter elements including a plurality of clear filter elements and a plurality of color-sensitive filter elements. The plurality of color-sensitive filter elements includes at least one first color-sensitive filter element sensitive to a first band of the visible color spectrum and at least one second color-sensitive filter element sensitive to a second band of the visible color spectrum different than the first band. The color filter array and the image sensor collectively provide raw image capture data at a plurality of pixels corresponding to individual sensor elements and corresponding filter elements. The image processor is configured to receive the raw image capture data and determine an output value for each pixel indicating the intensity of multiple color components for the pixel. The output value at each pixel is determined at least in part based on the raw image capture data at that pixel and at selected nearby pixels.

Another example aspect of the present disclosure is directed to a color filter array for an image capture device. The color filter array includes a plurality of clear filter elements, a plurality of first color-sensitive filter elements sensitive to a first band of the visible color spectrum, and a plurality of second color-sensitive filter elements sensitive to a second band of the visible color spectrum different than the first band. The plurality of clear filter elements are interspersed among the plurality of first color-sensitive filter elements and second color-sensitive filter elements in the color filter array to provide additional white light at corresponding locations across an image sensor surface.

Yet another example aspect of the present disclosure is directed to a method that includes filtering, by one or more color filter arrays, incoming light through an array of filter elements including a plurality of clear filter elements and a plurality of color-sensitive filter elements. The plurality of color-sensitive filter elements includes at least one first color-sensitive filter element sensitive to a first band of the visible color spectrum and at least one second color-sensitive filter element sensitive to a second band of the visible color spectrum different than the first band. The method also includes detecting, by one or more image sensors, raw image capture data indicative of an amount of incident light present at an image sensor including an array of sensor elements provided to receive output from the one or more color filter arrays. The one or more color filter arrays and the one or more image sensors collectively provide raw image capture data at a plurality of pixels. The method also includes determining, by one or more processing devices, multiple color components for each pixel based at least in part on the raw image capture data at that pixel or at one or more nearby pixels. The method also includes generating, by the one or more processing devices, a digital image based on the multiple color components determined for each pixel. The method also includes providing, by the one or more processing devices, the digital image as output data.

Other example aspects of the present disclosure are directed to systems, methods, apparatuses, tangible, non-transitory computer-readable media, user interfaces, memory devices, and vehicles including image detection and processing features.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts an example image capture device according to example embodiments of the present disclosure;

FIG. 2 depicts a first example arrangement of filter elements for a color filter array for an image capture device according to example embodiments of the present disclosure;

FIG. 3 depicts a second example arrangement of filter elements for a color filter array for an image capture device according to example embodiments of the present disclosure;

FIG. 4A depicts a third example arrangement of filter elements for a color filter array for an image capture device according to example embodiments of the present disclosure;

FIG. 4B depicts a fourth example arrangement of filter elements for a color filter array for an image capture device according to example embodiments of the present disclosure;

FIG. 5 provides a graphical illustration of quantum efficiency of an image sensor capturing different types of light within the visible color spectrum according to example aspects of the present disclosure;

FIG. 6 provides an example system of obtaining images and implementing vehicle control according to example embodiments of the present disclosure;

FIG. 7 depicts a flow diagram of an example method of obtaining images and implementing vehicle control according to example embodiments of the present disclosure; and

FIG. 8 depicts a flow diagram of an example method of processing images according to example embodiments of the present disclosure.

### DETAILED DESCRIPTION

Reference now will be made in detail to embodiments, one or more example(s) of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

Example aspects of the present disclosure are directed to capturing and processing images using an image capture device. Raw image capture data for a plurality of pixels can be obtained by passing incident light through a specialized Color Filter Array (CFA) before detecting an amount of incident light present at an image sensor. Detection of incident light at the image sensor can occur in accordance with a global shutter exposure protocol that exposes all sensor elements within the image sensor to incoming light at substantially the same time. The CFA can include a plurality of clear filter elements interspersed among a plurality of color-sensitive filter elements to provide additional white light at corresponding locations across a surface of the image sensor. In some examples, the color-sensitive filter elements can include red-sensitive filter elements, blue-sensitive filter elements and green-sensitive filter elements. In other examples, the color-sensitive elements can include red-sensitive filter elements and blue-sensitive filter elements, with green color components for each pixel being interpolated from data obtained by the red-sensitive and blue-sensitive filter elements. An image processor can interpolate the raw image capture data to determine an output value for each pixel indicating the intensity of multiple color components (e.g., red, green, and blue components) for that pixel. Pixel output values can be used to generate a digital image with significantly improved low-light performance. The improved digital images then can be further analyzed in autonomous vehicle applications, such as those involving object detection and vehicle control.

More particularly, an image capture device can include one or more initial filters, one or more color filter arrays and one or more image sensors. One or more initial filters can be provided to filter incoming light provided to an image capture device. Initial filters can include, for example, an infrared (IR) filter, a neutral density (NR) filter, an ultraviolet (UV) filter, or other filter type. A color filter array (CFA) including an array of filter elements can also filter incoming light provided incident to the image capture device before the light is detected at an array of sensor elements provided within an image sensor. In some examples, the image sensor can be a charge-coupled device (CCD) sensor or a complementary metal-oxide-semiconductor (CMOS) sensor. In some examples, the image sensor can obtain raw image capture data in accordance with a global shutter exposure protocol that exposes all sensor elements within the image sensor to incoming light at substantially the same time.

A color filter array can be positioned adjacent to a sensor array such raw image capture data is determined at a plurality of pixels corresponding to individual sensor elements and corresponding filter elements. The color filter array can include a plurality of clear filter elements and a plurality of color-sensitive filter elements including at least one first color-sensitive filter element sensitive to a first band of the visible color spectrum and at least one second color-sensitive filter element sensitive to a second band of the visible color spectrum. The clear filter elements and color-sensitive filter elements can be interspersed among one another such that each clear filter element is adjacent to at least two and as many as four color-sensitive filter elements. The distributed location of clear filter elements throughout the CFA provides additional white light in corresponding locations across a surface of an image sensor thus helping to improve image clarity in low light conditions.

In some examples, the CFA can include a plurality of clear filter elements and a plurality of color-sensitive filter elements sensitive to two different bands of the visible color spectrum. Color-sensitive filter elements can include one or more red-sensitive filter elements and one or more blue-sensitive filter elements. The CFA can be configured such that each clear filter element is adjacent to at least one red-sensitive filter element and at least one blue-sensitive filter element. In some examples, the CFA may not include any green-sensitive filter elements. In such instances, green color components at each pixel can be interpolated based on red and blue components determined from that pixel or selected adjacent, neighboring or nearby pixels. In some examples, the CFA can include a substantially similar number of clear filter elements as color-sensitive filter elements. In some examples, the CFA can include a substantially similar number of first color-sensitive filter elements (e.g., red-sensitive filter elements) as second color-sensitive filter elements (e.g., blue-sensitive filter elements). In some examples, the CFA can include a plurality of 2×2 pixel blocks, each pixel block consisting of two clear filter elements at opposing corners and a first color-sensitive filter element (e.g., a red-sensitive filter element) and a second color-sensitive filter element (e.g., a blue-sensitive filter element) at opposing corners.

In some examples, the CFA can include a plurality of clear filter elements and a plurality of color-sensitive filter elements variously sensitive to three different bands of the visible color spectrum. Color-sensitive filter elements can include, for example, a plurality of first color-sensitive filter elements (e.g., red-sensitive filter elements), a plurality of second color-sensitive filter elements (e.g., blue-sensitive filter elements), and a plurality of third color-sensitive filter elements (e.g., green-sensitive filter elements). The CFA can include a substantially similar number of clear filter elements as color-sensitive filter elements. The CFA can include a substantially similar number of first color-sensitive elements (e.g., red-sensitive color elements) as second color-sensitive elements (e.g., blue-sensitive color elements). The CFA can include a substantially similar number of third color-sensitive elements (e.g., green-sensitive filter elements) as the total combined number of first and second color-sensitive elements (e.g., red-sensitive and blue-sensitive filter elements). In some examples, the CFA can include a plurality of 4×4 pixel blocks, each pixel block consisting of alternating clear and color-sensitive filter elements such that eight (8) clear filter elements can be interspersed among four (4) green-sensitive filter elements, two (2) red-sensitive filter elements and two (2) blue-sensitive filter elements.

An image capture device also can include one or more image processing devices (e.g., image processors). The image processors can adjust one or more image parameters, interpolate color component contributions for each pixel, perform color correction and blending, and generate a digital image output. The image processors can receive raw image capture data and determine an output value for each pixel indicating the intensity of multiple color components (e.g., red, green, and blue components) for that pixel. The output value at each pixel can be determined at least in part based on the raw image capture data at that pixel and at selected nearby pixels. The output value at each pixel can indicate intensity levels for multiple color components using a variety of formats, including but not limited to an RGB format (R, G, B) including a triplet of red, green and blue color contribution values for each pixel, a hex color code (#aabbcc) format including a three-byte hexadecimal number consisting of six digits, with each byte or pair of characters representing the intensity of red, green and blue in the respective pixel color. Digital images can be generated using pixel output values corresponding to image sensor outputs detected at different particular times. The digital images can then be provided as output data for one or more subsequent applications.

In some examples, the digital images can be provided as output data routed to one or more processing devices in a vehicle control system. The digital images can be analyzed by the vehicle control system to identify at least one object in the digital image. In some examples, image objects of interest can include people, vehicles, roads, buildings, and/or navigation objects (e.g., street signs, traffic signals, etc.) An operational parameter of a vehicle (e.g., speed, direction, etc.) can be controlled in response to identification of at least one object in the digital image. In this manner, a vehicle can turn and/or stop upon conditions being detected within the digital images, including but not limited to the approach of another vehicle, a pedestrian crossing the road, a red traffic light being detected at an intersection, and the like.

In some examples, a vehicle control system configured to analyze digital image outputs from a disclosed image capture device can be provided as an integrated component in an autonomous vehicle. The autonomous vehicle can be configured to operate in one or more modes, for example, a fully autonomous operational mode, a semi-autonomous operational mode, a park mode, sleep mode, etc. A fully autonomous (e.g., self-driving) operational mode can be one in which the autonomous vehicle can provide driving and navigational operation with minimal and/or no interaction from a human driver present in the vehicle. A semi-autonomous (e.g., driver-assisted) operational mode can be one in which the autonomous vehicle operates with some interaction from a human driver present in the vehicle. Park and/or sleep modes can be used between operational modes while an autonomous vehicle waits to provide a subsequent service or recharges between operational modes.

The systems and methods described herein may provide a number of technical effects and benefits. For instance, image capture devices employing a color filter array including both clear filter elements and at least two different types of color-sensitive filter elements can be used to generate digital images having improved image stability. Enhanced image stability can be achieved at least in part by operating the image sensors in a global shutter exposure mode that exposes all sensor elements within the image sensor to incoming light at substantially the same time. The disclosed image capture devices can thus reduce potential distortion in generated digital images due to moving objects in the image frame.

Image stability improvements can be particularly advantageous for image capture devices used in conjunction with vehicle control systems for autonomous vehicles. Because image capture devices for an autonomous vehicle often seek to capture images of moving objects including other vehicles, pedestrians, changing traffic signs, and the like, improved image stability can advantageously lead to improved object detection within generated digital images. Image stability improvements also can be realized despite the constant movement of autonomous vehicles and associated image capture devices during operation, which can be moving relative to a surrounding environment at different rates of speed, including high speeds in some instances.

The systems and methods described herein may also provide a technical effect and benefit of providing improved image clarity. Enhanced image clarity is possible at least in part by allowing additional white light through clear filter elements in the CFA and onto corresponding locations across an image sensor surface. The disclosed image capture devices can thus have improved low light sensitivity and be capable of generating digital images having improved image quality in a variety of image capture conditions. For instance, regardless of whether the disclosed image capture devices are operating at different times of day (e.g., day, night, twilight, etc.), in different seasons of the year (e.g., winter, spring, summer, fall), during different weather conditions (e.g., sun, rain, snow, fog, etc.), digital images having improved clarity despite available lighting conditions can be generated. Improved image clarity can also yield corresponding improvements to the accuracy of object detection within digital images and corresponding vehicle control in autonomous vehicles based on such object detection.

The systems and methods described herein may also provide a technical effect and benefit of providing an unexpected result pertaining to performance efficiency in object detection for vehicle applications. For some vehicle applications, color images have proven to be better for object detection than monochrome (e.g., black and white) images. Color images can be helpful for detecting specific types of objects, such as current illumination states (e.g., red, yellow, green) of a traffic light or other changing road signage. In some test examples, object detection using monochrome images obtained without a color filter array were found to yield around 50% of a desired performance rating relative to color images obtained using a traditional Bayer color filter array. One might expect that a color filter array as described herein, that excludes green-sensitive filter elements and can include clear filter elements at up to half of the pixel locations, could suffer from a similar degradation in object detection performance. However, test examples of object detection using images obtained using a color filter array having clear, red and blue filter elements as disclosed herein were found to yield greater than about 90% of a desired performance rating relative to color images obtained using a traditional Bayer color filter array, while simultaneously achieving significant enhancements to image clarity in low light conditions. The unexpected result of having improved image clarity with negligible effect on object detection performance provides a substantial benefit for vehicle applications.

The systems and methods of the present disclosure also can provide an improvement to computing technology provided within image processors and/or vehicle computing systems. Image processors are able to advantageously determine pixel output values for a variety of color components at each pixel due to the disclosed color filter array configurations and subsequent image processing. By reducing requirements for additional image filtering and/or processing to achieve desired levels of image clarity and stability, the operating speed of image processors can be improved and potential latency within an image processing system can be reduced. Similarly, vehicle control systems that use digital images generated as an output of the disclosed image capture devices can have improved operational speed, more accurate detection of stationary or moving objects within the digital images, and more seamless and efficient vehicle control.

The image capture features disclosed herein provide an additional or alternative solution to the problem of creating clear and stable digital images in autonomous vehicle applications. In some examples, improvements can be achieved without requiring a rolling-shutter operational mode for the image sensor. In some examples, improvements can be achieved without requiring an additional light source (e.g., camera flash, infrared light, etc.) adjacent to the image capture device for use in low light conditions. Although alternative features such as rolling-shutter image sensors and/or additional light sources may not be required, it should be appreciated that some embodiments can include such features in addition to the disclosed color filter array (CFA) and associated image capture device components.

With reference now to the FIGS., example embodiments of the present disclosure will be discussed in further detail. FIG. 1 depicts an example image capture device 100 according to example embodiments of the present disclosure. Image capture device 100 can include a shutter 102, one or more initial filters 104, a color filter array 106, an image sensor 108, and an image processor 110. Image capture device 100 can also have additional conventional components not illustrated in FIG. 1 as would be understood by one of ordinary skill in the art.

With more particular reference to FIG. 1, shutter 102 can be selectively controlled between open and closed positions. When shutter 102 is controlled to an open position, incoming light 112 passes through a lens, optional initial filters 104 and color filter array 106 before reaching image sensor 108. The one or more initial filters 104 can be positioned before, between and/or after the shutter 102 to filter incoming light 112 provided to image capture device 100. Initial filter(s) can include, for example, an infrared (IR) filter, a neutral density (NR) filter, an ultraviolet (UV) filter, or other filter type. Various operational parameters of shutter 102 can be controlled in accordance with an image capture device 100 as disclosed herein, including but not limited to an exposure time (e.g., shutter speed) and an exposure protocol. In some examples, image sensor 108 can obtain raw image capture data 114 in accordance with a global shutter exposure protocol by which shutter 102 is controlled to expose the entire image sensor 108 to incoming light 112 at substantially the same time.

In some examples, the image sensor 108 can be a charge-coupled device (CCD) sensor or a complementary metal-oxide-semiconductor (CMOS) sensor, although other image sensors can also be employed. Image sensor 108 can include an array of image sensor elements 116 configured to detect incoming light 112 provided incident to a surface 118 of image sensor 108. Each image sensor element 116 can detect incoming light 112 by detecting the amount of light that falls thereon and converting the received amount of light into a corresponding electric signal. For instance, the more light captured at each image sensor element 116, the stronger the electric signal generated by that sensor element 116. In some examples, each image sensor element 116 can include a photodiode and an amplifier along with additional integrated circuit components configured to generate the electric signal representative of an amount of captured light at each image sensor element 116. The electric signal captured at each image sensor element 116 can provide raw image capture data 114 at a plurality of pixels 124, each pixel 124 corresponding to a corresponding image sensor element 116 within image sensor 108.

Referring still to FIG. 1, color filter array 106 can be positioned directly or indirectly adjacent to image sensor 108 for filtering the incoming light 112 provided incident to the surface 118 of the image sensor 108. FIG. 1 depicts color filter array 106 and image sensor 108 in an exploded perspective view, although in operation the color filter array 106 would be translated along directional lines 115 to be positioned adjacent to surface 118 of image sensor 108. Color filter array 106 can include an array of filter elements 120a-d, such that each filter element 120a-d filters incoming light 112 captured by a corresponding sensor element 116. In this manner, color filter array 106 and image sensor 108 collectively provide raw image capture data 114 at a plurality of pixels corresponding to individual image sensor elements 116 and corresponding filter elements 120a-d. Although a limited number of filter elements 120a-d, image sensor elements 116, and number of pixels 124 are depicted in FIG. 1, it should be appreciated that a color filter array 106 and an image sensor 108 are constituted by a much larger number of elements and resulting image pixels. In addition, although the filter elements 120a-d and image sensor elements 116 are depicted as generally square in shape, it should be appreciated that such elements can be formed in a variety of configurations including but not limited to hexagons, diamonds, rectangles, other polygons and the like.

Referring still to FIG. 1, color filter array 106 can include a plurality of filter elements 120a-d that form 2×2 pixel blocks that can be repeated within the various rows and columns of color filter array 106. Color filter array 106 can include a plurality of clear filter elements 120b, 120c and a plurality of color-sensitive filter elements 120a, 120d. The plurality of color-sensitive filter elements 120a, 120d can include at least one first color-sensitive filter element 120a sensitive to a first band of the visible color spectrum and at least one second color-sensitive filter element 120d sensitive to a second band of the visible color spectrum. The second band of the visible color spectrum can be different than the first band of the visible color spectrum. Color-sensitive filter elements 120a, 120d can be sensitive to at least two different bands in the visible color spectrum to help facilitate interpolation of multiple color components at each pixel. The visible color spectrum can correspond to the spectrum of light defined by a wavelength range of between about 400 and 700 nanometers (nm), which results in visible light appearing within a range of colors including red, orange, yellow, green, blue, indigo, and other blends of these colors. A color-sensitive filter element 120a, 120d that is sensitive to a particular color is configured to allow light of that color to pass through while other colors in the spectrum of visible light are absorbed and/or blocked from image sensor 108. In other words, a color-sensitive filter element 120a, 120d is selectively transparent in the region of the color spectrum corresponding to that particular color.

Color filter array 106 and other color filter arrays disclosed herein can variously include one or more color-sensitive filter elements, for example first color-sensitive elements, second color-sensitive elements and/or third color-sensitive elements. Specific examples described herein use color filter arrays designed for different color sensitivities in the “Red/Green/Blue” or “RGB” color space. However, it should be appreciated that different color sensitivities can be used to create other color filter arrays in accordance with the disclosed technology. For instance, color sensitivities in the “Cyan/Magenta/Yellow” or “CMY” color space can employed. In such examples, a yellow-sensitive filter element in a CMY color filter array can generally correspond to the green-sensitive filter element in an RGB color filter array. Cyan-sensitive and magenta-sensitive filter elements in a CMY color filter array can generally correspond to the red-sensitive and blue-sensitive filter elements in an RGB color filter array. Still further color filter array alternatives can be designed to target different particular ranges of the visible color spectrum, from which color component information can be interpolated in accordance with the disclosed technology.

Referring still to FIG. 1, the plurality of clear filter elements 120b, 120c are interspersed among the plurality of first color-sensitive filter elements 120a and second color-sensitive filter elements 120d in a distributed fashion within color filter array 106 to provide additional white light at corresponding locations across surface 118 of image sensor 108, thus helping to improve image clarity across different operating conditions. In some examples, the clear filter elements 120b, 120c are interspersed among one another such that each clear filter element 120b, 120c is adjacent to at least two and as many as four color-sensitive filter elements 120a, 120d. In some examples, color filter array 106 is configured such that each clear filter element 120b, 120c is adjacent to at least one first color-sensitive filter element 120a and at least one second color-sensitive filter element 120d.

Inclusion of clear filter elements 120b, 120c is helpful to provide a sufficient amount of light for operation of image capture device 100 in a variety of operating conditions. Each color-sensitive filter element 120a, 120d effectively blocks about two-thirds of the incoming light 112 at each image sensor element 116, corresponding to the bands outside of its color-specific sensitivity. However, clear filter elements 120b, 120c allow the full spectrum of visible light to reach corresponding image sensor elements 116. This configuration of color filter array 106 can help image capture device 100 provide improved digital image outputs when the image capture device is operating at different times of day (e.g., day, night, twilight, etc.), in different seasons of the year (e.g., winter, spring, summer, fall) and/or during different weather conditions (e.g., sun, rain, snow, fog, etc.). This improvement in image quality can be especially beneficial for vehicle applications, including applications in which autonomous vehicles use image capture devices for object detection, navigation and the like.

In some implementations, image capture device 100 can additionally include an infrared (IR) light source that is configured to help enhance illumination of objects associated with the incoming light 112. This can be especially helpful in low light situations, poor weather conditions and the like to ensure a sufficient amount of light for operation of image capture device 100 in a variety of operating conditions, as described above.

In some implementations, such as when image capture device 100 includes an IR light source, color filter array 106 can additionally include at least one third color-sensitive filter element (e.g., a green-sensitive filter element). For example, one of the clear filter elements 120b, 120c in color filter array 106 can be replaced with a third color-sensitive filter element such that color filter array 106 includes a plurality of 2×2 pixel blocks, each pixel block consisting of a first color-sensitive filter element, a second color-sensitive filter element, a third color-sensitive filter element, and a clear filter element.

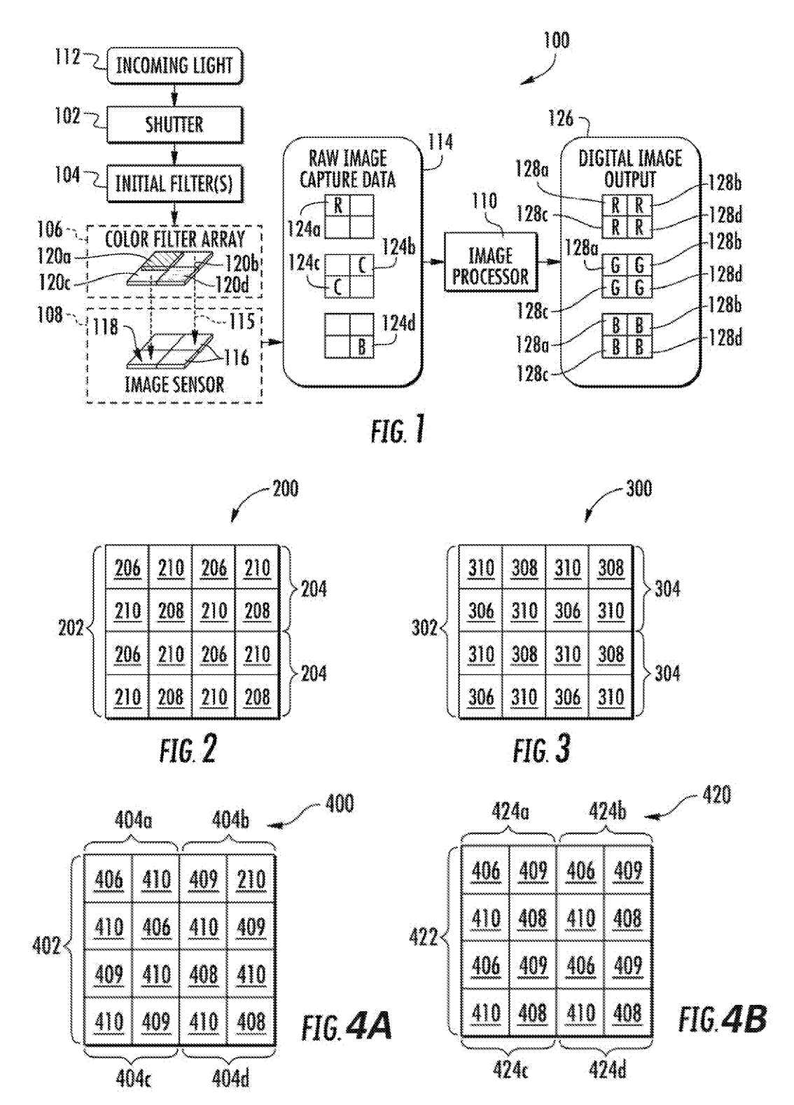

In some examples, color filter array 106 can include a plurality of 2×2 pixel blocks, each pixel block consisting of two clear filter elements 120b, 120c at opposing corners and a first color-sensitive filter element 120a and a second color-sensitive filter element 120d at opposing corners. In some examples, each first-color sensitive filter element 120a can be a red-sensitive filter element that is sensitive to a first band of the visible color spectrum. Red-sensitive filter elements can thus be designed to allow red light (e.g., light characterized by a wavelength of between about 620-750 nanometers (nm) or a corresponding frequency of between about 400-484 Terahertz (THz)) to pass through while other colors in the spectrum of visible light are absorbed. Each second color-sensitive filter element 120d can be a blue-sensitive filter element that is sensitive to a second band of the visible color spectrum that is different than the first band. Blue-sensitive filter elements can thus be designed to allow blue light (e.g., light characterized by a wavelength of between about 450-494 nm and/or a corresponding frequency of between about 606-668 THz) to pass through while other colors in the spectrum of visible light are absorbed. Alternative configurations of color-sensitive filter elements and clear filter elements will be discussed with reference to FIGS. 2-4.

Referring still to FIG. 1, an image sensor 108 operating with a color filter array 106 including color-sensitive filter elements 120a, 120d and clear filter elements 120b, 120c as illustrated will yield raw image capture data 114 at each of a plurality of raw data pixels 124. Raw image capture data 114 in each 2×2 pixel block can include a first raw data pixel 124a having a first color component (e.g., a red color component), second raw data pixel 124b and third raw data pixel 124c having a monochrome or clear component, and a fourth raw data pixel 124d having a second color component (e.g., a blue color component). One or more processing devices (e.g., image processor(s)) 110 can be configured to receive the raw image capture data 114 and determine an output value for each output pixel 128 indicating the intensity of multiple color components for that output pixel 128. For instance, each output pixel 128a, 128b, 128c and 128d of FIG. 1 can include a first color component (e.g., a red (R) color component), a second color component (e.g., a green (G) color component) and a third color component (e.g., a blue (B) color component).

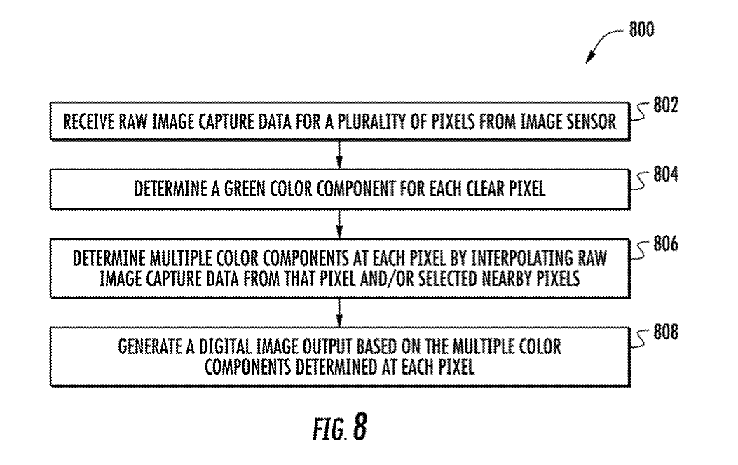

Output values at each pixel 128a-d can be determined at least in part based on the raw image capture data 114 at that pixel and at selected nearby pixels. In addition to interpolating color component contributions for each pixel, image processors 110 can also adjust one or more image parameters, perform color correction and blending, and/or other image processing steps or functions before ultimately generating digital image output 126. Successive iterations of digital image output 126 can be generated using pixel output values corresponding to image sensor outputs detected at different increments of times. The digital image output 126 can then be provided as output data for one or more subsequent applications. For example, digital image output 126 can be provided as output data routed to one or more processing devices in a vehicle control system, such as described in more detail in FIG. 6.

Output values at each pixel of digital image output 126 can indicate the intensity of multiple color components per pixel (e.g., a first color component, second color component, and third color component.) As such, image processor 110 can generate a digital image output 126 that has multiple color components (e.g., a red color component, a green color component and a blue color component) for each output pixel 128 by utilizing raw image capture data 112 obtained at that pixel as well as raw image capture data obtained at selected nearby pixels in order to interpolate other color components for the given output pixel 128. The output value at each pixel 128 can indicate intensity levels for multiple color components using a variety of formats. In some examples, each pixel is determined using an RGB format including red, green and blue color components or a CMY format including cyan, magenta and yellow color components. In other examples, color contribution values for each pixel are determined using a hex color code (#aabbcc) format including a three-byte hexadecimal number consisting of six digits, with each byte or pair of characters (aa, bb, and cc) representing the intensity of first, second and third color components in the respective pixel. Additional details regarding the interpolation of color components are described with reference to FIG. 8.

Referring now to FIGS. 2-4, portions of three example color filter arrays 200, 300, 400 are depicted. Color filter arrays 200, 300, 400 are depicted as 4×4 pixel blocks containing sixteen total pixels, although this is merely a portion of an entire color filter array that can be provided within image capture device 100. Each portion depicted in FIGS. 2-4 can be repeated across blocks of rows and columns within a color filter array 106, with enough filter elements 120 to match the number of image sensor elements 116 included in image sensor 108.

With more particular reference to FIG. 2, color filter array 200 can include 4×4 pixel blocks 202 that include 2×2 pixel blocks 204 similar to those depicted in FIG. 1. Color filter array 200 can include a plurality of first color-sensitive filter elements 206 sensitive to a first band of the visible color spectrum (e.g., red-sensitive filter elements) and a plurality of second color-sensitive filter elements 208 sensitive to a second band of the visible color spectrum (e.g., blue-sensitive filter elements). Color filter array 200 may not include any third color-sensitive filter elements (e.g., green-sensitive filter elements). However, an image processor is configured to interpolate a third (e.g., green) color component at each pixel based on red and blue color components determined from that pixel or selected nearby pixels.

Referring still to FIG. 2, a plurality of clear filter elements 210 can be interspersed among the plurality of first color-sensitive filter elements 206 and second color-sensitive filter elements 208 in the color filter array 200 to provide additional white light at corresponding locations across an image sensor surface. Each clear filter element 210 can be adjacent to four color-sensitive filter elements (two first color-sensitive filter elements 206 and two second color-sensitive filter elements 208). In some examples, color filter array 200 can include a substantially similar number of clear filter elements 210 as color-sensitive filter elements 206, 208. In some examples, color filter array 200 can include a substantially similar number of first color-sensitive filter elements 206 as second color-sensitive filter elements 208. Each 2×2 pixel block 204 in color filter array 200 can include two clear filter elements 210 at opposing corners and a first color-sensitive filter element (e.g., a red-sensitive filter element) 206 and a second color-sensitive filter element (e.g., a blue-sensitive filter element) 208 at opposing corners. In the example of FIG. 2, the first color-sensitive filter elements 206 can be provided in an upper left quadrant of each 2×2 pixel block 204, the second color-sensitive filter elements 208 can be provided in a lower right quadrant of each 2×2 pixel block 204, and clear filter elements 210 can be provided in an upper right quadrant and lower left quadrant of each 2×2 pixel block 204.

With more particular reference to FIG. 3, color filter array 300 can include 4×4 pixel blocks 302 that include 2×2 pixel blocks 304. Color filter array 300 can include a plurality of first color-sensitive filter elements 306 sensitive to a first band of the visible color spectrum (e.g., red-sensitive filter elements) and a plurality of second color-sensitive filter elements 308 sensitive to a second band of the visible color spectrum (e.g., blue-sensitive filter elements). Color filter array 300 may not include any third color-sensitive filter elements (e.g., green-sensitive filter elements). However, an image processor can be configured to interpolate a third (e.g., green) color component at each pixel based on red and blue color components determined from that pixel or selected nearby pixels.

Referring still to FIG. 3, a plurality of clear filter elements 310 can be interspersed among the plurality of first color-sensitive filter elements 306 and second color-sensitive filter elements 308 in the color filter array 300 to provide additional white light at corresponding locations across an image sensor surface. Each clear filter element 310 can be adjacent to at least one first color-sensitive filter element 306 and at least one second color-sensitive filter element 308. Each clear filter element 310 that is not located along an edge of color filter array 300 (e.g., an inner filter element as opposed to an outer filter element) can be adjacent to four color-sensitive filter elements (two first color-sensitive filter elements 306 and two second color-sensitive filter elements 308). In some examples, color filter array 300 can include a substantially similar number of clear filter elements 310 as color-sensitive filter elements 306, 308. In some examples, color filter array 300 can include a substantially similar number of first color-sensitive filter elements 306 as second color-sensitive filter elements 308. Each 2×2 pixel block 304 in color filter array 300 can include two clear filter elements 310 at opposing corners and a first color-sensitive filter element (e.g., a red-sensitive filter element) 306 and a second color-sensitive filter element (e.g., a blue-sensitive filter element) 308 at opposing corners. In the example of FIG. 3, the first color-sensitive filter elements 306 can be provided in a lower left quadrant of each 2×2 pixel block 304, the second color-sensitive filter elements 308 can be provided in an upper right quadrant of each 2×2 pixel block 304, and clear filter elements 310 can be provided in an upper left quadrant and lower right quadrant of each 2×2 pixel block 304.

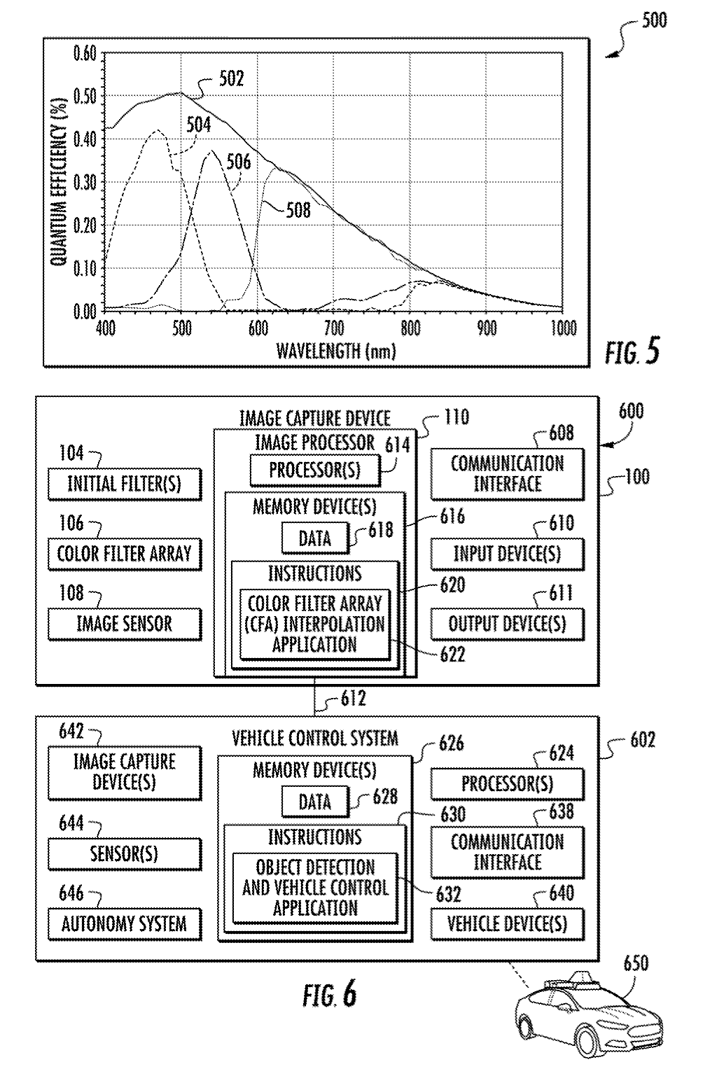

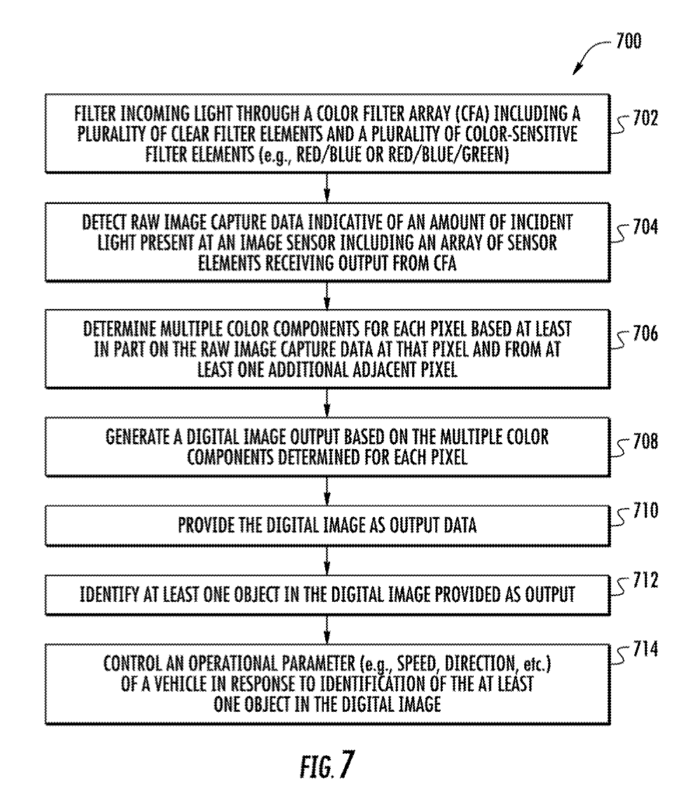

With more particular reference to FIGS. 4A and 4B, color filter arrays 400 and 420 can respectively include a plurality of first color-sensitive filter elements 406 sensitive to a first band of the visible color spectrum (e.g., red-sensitive filter elements), a plurality of second color-sensitive filter elements 408 sensitive to a second band of the visible color spectrum different than the first band (e.g., blue-sensitive filter elements), and a plurality of third color-sensitive filter elements 409 sensitive to a third band of the visible color spectrum different than the first and second bands (e.g., green-sensitive filter elements).

In FIG. 4A, color filter array 400 can include 4×4 pixel blocks 402 that include 2×2 pixel blocks 404a-404d, respectively. Each 4×4 pixel block 402 within color filter array 400 can include alternating clear and color-sensitive filter elements such that eight (8) clear filter elements can be interspersed among four (4) green-sensitive filter elements, two (2) red-sensitive filter elements and two (2) blue-sensitive filter elements.

A plurality of clear filter elements 410 can be interspersed among the plurality of first color-sensitive filter elements 406, second color-sensitive filter elements 408, and third color-sensitive filter elements 409 in the color filter array 400 to provide additional white light at corresponding locations across an image sensor surface. In some examples, color filter array 400 can include a substantially similar number of clear filter elements 410 as color-sensitive filter elements 406, 408, 409. In some examples, color filter array 400 can include a substantially similar number of first color-sensitive filter elements 406 as second color-sensitive filter elements 408. In some examples, the number of third color-sensitive filter elements 409 is substantially similar to the total combined number of first color-sensitive filter elements 406 and second color-sensitive filter elements 408.

Referring still to FIG. 4A, a first 2×2 pixel block 404a provided in an upper left quadrant of 4×4 pixel block 402 of color filter array 400 can include two clear filter elements 410 at opposing corners and two first color-sensitive filter elements (e.g., red-sensitive filter elements) 406 at opposing corners. A second 2×2 pixel block 404b provided in an upper right quadrant of 4×4 pixel block 402 and third 2×2 pixel block 404c in lower left quadrant of 4×4 pixel block 402 in color filter array 400 can respectively include two clear filter elements 410 at opposing corners and two third color-sensitive filter elements (e.g., a green-sensitive filter elements) 409 at opposing corners. A fourth 2×2 pixel block 404d in color filter array 400 can include two clear filter elements at opposing corners and two second color-sensitive filter elements (e.g., blue-sensitive filter elements) 408 at opposing corners. It should be appreciated that variations to the specific configuration of filter elements within color filter array 400 of FIG. 4A can also be employed. In some examples, the locations of 2×2 pixel block 404a and 2×2 pixel block 404d within 4×4 pixel block 402 can be swapped with one another. In another example, 2×2 pixel blocks 404b and 404c are switched to locations in the upper left and lower right quadrants of 4×4 pixel block 402, while 2×2 pixel blocks 404a and 404d are located in the upper right and lower left quadrants of 4×4 pixel block 402. The location of clear filter elements 410 and color-sensitive filter elements 406, 408, 409 within each 2×2 pixel block 404a-404d can also be rotated.

In FIG. 4B, color filter array 420 can include 4×4 pixel blocks 422 that include 2×2 pixel blocks 424a-424d, respectively. Each 2×2 pixel block 424a-424d within color filter array 420 can include a first color-sensitive filter element (e.g., a red-sensitive filter element) 406, a second color-sensitive filter element (e.g., a blue-sensitive filter element) 408, a third color-sensitive filter element (e.g., a green color-sensitive filter element) 409 and a clear filter element 410. In this manner, a plurality of clear filter elements 410 can be interspersed among the plurality of first color-sensitive filter elements 406, second color-sensitive filter elements 408, and third color-sensitive filter elements 409 in the color filter array 420 to provide additional white light at corresponding locations across an image sensor surface. In some examples, color filter array 420 can include a number of clear filter elements 410, a number of first color sensitive filter elements (e.g., red-sensitive filter elements) 406, a number of second color-sensitive filter elements (e.g., blue-sensitive filter elements) 408, and a number of third color-sensitive filter elements (e.g., green-sensitive filter elements) 409 that are substantially similar. In the example of FIG. 4B, a first color-sensitive filter element 406 and second color-sensitive filter element 408 are located at opposing corners within each 2×2 pixel block 424a-424d, while a third color-sensitive filter element 409 and clear filter element 410 are located at different opposing corners within each 2×2 pixel block 424a-424d.

FIG. 5 provides a graphical illustration 500 of the quantum efficiency versus wavelength of image sensor elements having different characteristics as described herein. Quantum efficiency plotted in FIG. 5 is a measurement of the electrical sensitivity to light of the image sensor 108. Because different image sensor elements 116 have different corresponding filter elements 120 at various locations within a color filter array 106, the quantum efficiency at each image sensor element and the corresponding data value at each pixel can vary. For example, image sensor elements that capture light filtered by a clear filter element have a relatively high quantum efficiency over the entire spectrum of visible light (e.g., between about 400-700 nm) as depicted by curve 502. Image sensor elements that capture light filtered by a blue filter element have lower quantum efficiency peaking at a wavelength of about 450 nm as depicted by curve 504. Image sensor elements that capture light filtered by a red filter element also have a lower quantum efficiency peaking at a wavelength of about 650 nm as depicted by curve 508. Image sensor elements that capture light filtered by a green filter element have a quantum efficiency that peaks around 550 nm as depicted by curve 506, and is typically slightly higher than the quantum efficiency of light filtered by blue and red filter elements as depicted by curves 504 and 508.

Knowledge of the quantum efficiencies depicted in the graphical illustration 500 of FIG. 5 can help provide an understanding of certain advantages of the disclosed color filter arrays as well as color filter array interpolation techniques used herein. More particularly, the quantum efficiency depicted by curve 502 helps illustrate advantages of color filter arrays that include a plurality of clear filter elements. Each clear filter element allows about three times as much light to be detected at corresponding image sensor elements as image sensor elements having a corresponding color-sensitive filter element. This is because color-sensitive filter elements effectively absorb or block two-thirds of available light from reaching an image sensor element. Availability of the additional light intensity at image sensor elements having corresponding clear filter elements can yield digital image outputs with increased image clarity, especially in low light conditions. In addition, the relative contributions of blue, green and red light such as depicted by curves 504, 506 and 508, respectively, to total light intensity depicted by curve 502 at a given pixel can be used to interpolate color components. In some color filter array examples that exclude green-sensitive filter elements, green color component values (e.g., curve 506) can be interpolated by subtracting blue and red color components (depicted by curves 504 and 508) from curve 502.

Referring now to FIG. 6, an example system 600 of obtaining images and implementing vehicle control according to example embodiments of the present disclosure can include an image capture device 100 and a vehicle control system 602. Some components of image capture device 100 are similar to those illustrated in FIG. 1, including one or more initial filters 104, color filter array 106, image sensor 108, and image processor 110. Image capture device 100 and vehicle control system 602 can be configured to communicate via one or more communication channels 612. Vehicle control system 602 can be provided as an integrated component of or associated with operation of a vehicle 650.

Image processor 110 and vehicle control system 602 can respectively include one or more processor(s) 614, 624 along with one or more memory device(s) 616, 626 that can collectively function as respective computing devices. The one or more processor(s) 614, 624 can be any suitable processing device such as a microprocessor, microcontroller, integrated circuit, an application specific integrated circuit (ASIC), a digital signal processor (DSP), a field-programmable gate array (FPGA), logic device, one or more central processing units (CPUs), processing units performing other specialized calculations, etc. The processor(s) 614, 624 can be a single processor or a plurality of processors that are operatively and/or selectively connected.

The memory device(s) 616, 626 can include one or more non-transitory computer-readable storage media, such as RAM, ROM, EEPROM, EPROM, flash memory devices, magnetic disks, etc., and/or combinations thereof. The memory device(s) 616, 626 can store information that can be accessed by the one or more processor(s) 614, 624. For instance, the memory device(s) 616 can include computer-readable instructions 620 that can be executed by the one or more processor(s) 614. Similarly, memory device(s) 616 can include computer-readable instructions 630 that can be executed by the one or more processor(s) 624. The instructions 620, 630 can be software written in any suitable programming language, firmware implemented with various controllable logic devices, and/or can be implemented in hardware. Additionally, and/or alternatively, the instructions 620, 630 can be executed in logically and/or virtually separate threads on processor(s) 614, 624. The instructions 620, 630 can be any set of instructions that when executed by the one or more processor(s) 614, 624 cause the one or more processor(s) 614, 624 to perform operations.

For example, the memory device(s) 616 can store instructions that when executed by the one or more processor(s) 614 cause the one or more processor(s) 614 to perform operations associated with a color filter array (CFA) color interpolation application 622. CFA color interpolation application 622 can be defined in terms of instructions for determining one or more output values including multiple color components for each pixel within an image (e.g., one or more portions of method 800) and/or any other operations or functions for processing raw image data or resulting images, as described herein. Memory device(s) 626 can store instructions that when executed by the one or more processor(s) 624 cause the one or more processor(s) 624 to perform operations associated with an object detection and vehicle control application 632. Object detection and vehicle control application 632 can be defined in terms of instructions for performing operations including identifying objects in digital image outputs, controlling operational parameters of a vehicle in response to identification of the detected objects within the digital image outputs, and/or any other operations or functions related to vehicle operation.

The one or more memory device(s) 616, 626 can store data 618, 628 that can be retrieved, manipulated, created, and/or stored by the one or more processor(s) 614, 624. The data 618 can include, for instance, raw image capture data 114, digital image outputs 126, or other image-related data or parameters. Data 628 can include, for instance, digital image outputs from image capture device 100, data associated with a vehicle 650, data acquired by vehicle sensors or other image capture devices, 2D and/or 3D map data associated with a past, current and/or future operating environment of vehicle 650 as obtained from one or more remote computing systems and/or local memory devices, data identifying the surrounding environment of a vehicle 650, and/or other data or information. The data 618, 628 can be stored in one or more database(s). The one or more database(s) can be split up so that they can be provided in multiple locations.

Image capture device 100 and vehicle control system 602 can respectively include a communication interface 608, 638 used to communicate with one another and one or more other component(s) of the system 600 or other systems of vehicle 650. The communication interface 608, 638 can include any suitable components for interfacing with one or more communication channels 612, including for example, transmitters, receivers, ports, controllers, antennas, or other suitable hardware and/or software. Communication channel 612 can be any type of communication channel, such one or more data bus(es) (e.g., controller area network (CAN)), an on-board diagnostics connector (e.g., OBD-II) and/or a combination of wired and/or wireless communication links for sending and/or receiving data, messages, signals, etc. among devices/systems. Communication channel 612 can additionally or alternatively include one or more networks, such as a local area network (e.g. intranet), wide area network (e.g. Internet), wireless LAN network (e.g., via Wi-Fi), cellular network, a SATCOM network, VHF network, a HF network, a WiMAX based network, and/or any other suitable communications network (or combination thereof) for transmitting data to and/or from the vehicle image capture device 100 and/or vehicle control system 602 and/or other local vehicle systems or associated server-based processing or control systems located remotely from a vehicle 650. The communication channel 612 can include a direct connection between one or more components of the system 600. In general, communication between one or more component(s) of the system 600 can be carried via communication interface using any type of wired and/or wireless connection, using a variety of communication protocols (e.g. TCP/IP, HTTP, SMTP, FTP), encodings or formats (e.g. HTML, XML), and/or protection schemes (e.g. VPN, secure HTTP, SSL).

Image capture device 100 also can include one or more input devices 610 and/or one or more output devices 611. An input device 610 can include, for example, devices for receiving information from a user, such as a touch screen, touch pad, mouse, data entry keys, speakers, a microphone suitable for voice recognition, etc. An input device 610 can be used, for example, by a user to select controllable inputs for operation of the image capture device 100 (e.g., shutter, ISO, white balance, focus, exposure, etc.) An output device 611 can be used, for example, to provide digital image outputs to a vehicle operator. For example, an output device 611 can include a display device (e.g., display screen, CRT, LCD), which can include hardware for displaying an image or other communication to a user. Additionally, and/or alternatively, an output device(s) can include an audio output device (e.g., speaker) and/or device for providing haptic feedback (e.g., vibration).

Vehicle control system 602 can include one or more controllable vehicle device(s) 640, such as but not limited to acceleration and/or deceleration/braking pedals, buttons or other control devices, steering wheels or other directional devices, and the like. Vehicle device(s) 640 can be selectively controlled based on digital image outputs generated by image capture device 100 and/or specific image processing conducted on the digital image outputs (e.g., detection of objects including but not limited to one or more of a person (e.g., a pedestrian), an animal, a vehicle, a bicycle, a road, a road feature, a navigational object such as signage, a building, an object, road conditions (e.g., curves, potholes, dips, bumps, changes in grade), distances between vehicle 650 and other vehicles and/or objects, etc.

A vehicle 650 incorporating vehicle control system 602 can be an automobile, an aircraft, and/or another type of vehicle. In some examples, a vehicle 650 incorporating vehicle control system 602 can be an autonomous vehicle that can drive, navigate, operate, etc. with minimal and/or no interaction from a human driver. An autonomous vehicle 650 can be configured to operate in one or more mode(s) such as, for example, a fully autonomous operational mode and/or a semi-autonomous operational mode. A fully autonomous (e.g., self-driving) operational mode can be one in which the autonomous vehicle can provide driving and navigational operation with minimal and/or no interaction from a human driver present in the vehicle. A semi-autonomous operational mode can be one in which the autonomous vehicle can operate with some interaction from a human driver present in the vehicle.

When image capture device 100 is provided as an integral component within an autonomous vehicle 650, image capture device 100 can be located in the interior and/or on the exterior of such a vehicle 650. The image capture device(s) 100 can be configured to acquire image data to allow the vehicle 650 to implement one or more machine vision techniques (e.g., to detect objects in the surrounding environment). Digital image outputs from image capture device 100 can be combined with data obtained from other image capture devices 642, including but not limited to light detection and ranging (or radar) device(s) (LIDAR systems), two-dimensional image capture devices, three-dimensional image capture devices, static image capture devices, dynamic (e.g., rotating, revolving) image capture devices, video capture devices (e.g., video recorders), lane detectors, scanners, optical readers, electric eyes, and/or other suitable types of image capture devices. Digital image outputs from image capture device 100 can be additionally or alternatively combined with data from one or more sensor(s) 644 such as motion sensors, pressure sensors, temperature sensors, humidity sensors, RADAR, sonar, radios, medium-range and long-range sensors (e.g., for obtaining information associated with the vehicle's surroundings), global positioning system (GPS) equipment, proximity sensors, and/or any other types of sensors for obtaining data associated with the vehicle 650 and/or relevant to the operation of the vehicle 650 (e.g., in an autonomous mode).

When vehicle 650 is an autonomous vehicle, vehicle control system 602 can include an autonomy system 646 configured to allow the vehicle 650 to operate in an autonomous mode (e.g., fully autonomous mode, semi-autonomous mode). For instance, the autonomy system 646 can obtain data associated with the vehicle 650 (e.g., acquired by the image capture device 100 as well as other image capture device(s) 642 and/or sensor(s) 644). The autonomy system 646 can interface with processor(s) 624 and memory device(s) 626 to help control various functions of the vehicle 650 based, at least in part, on the data acquired by the image capture device 100 as well as other image capture device(s) 642 and/or sensor(s) 644 to implement an autonomous mode. For example, the autonomy system 646 can include various models to detect objects (e.g., people, animals, vehicles, bicycles, buildings, roads, road features, road conditions (e.g., curves, potholes, dips, bumps, changes in grade), navigational objects such as signage, distances between vehicle 650 and other vehicles and/or objects, etc.) based, at least in part, on the acquired image data, other sensed data and/or map data. In some implementations, the autonomy system 646 can include machine-learned models that use the digital image outputs acquired by the image capture device 100 or other data acquisition system(s) and/or the map data to help operate the vehicle 650. The autonomy system 646 can be configured to predict the position and/or movement (or lack thereof) of such objects (e.g., using one or more odometry techniques). The autonomy system 646 can be configured to plan the motion of the vehicle 650 based, at least in part, on such predictions. The autonomy system 646 can include a navigation system and can be configured to implement the planned motion to appropriately navigate the vehicle 650 with minimal and/or no human-driver intervention. For example, the autonomy system can regulate vehicle speed, acceleration, deceleration, steering, and/or the operation of components to follow the planned motion. In this way, the autonomy system 646 can allow an autonomous vehicle 650 to operate in a fully and/or semi-autonomous mode.

The technology discussed herein makes reference to servers, databases, software applications, and other computer-based systems, as well as actions taken and information sent to and from such systems. One of ordinary skill in the art will recognize that the inherent flexibility of computer-based systems allows for a great variety of possible configurations, combinations, and divisions of tasks and functionality between and among components. For instance, server processes discussed herein can be implemented using a single server or multiple servers working in combination. Databases and applications can be implemented on a single system or distributed across multiple systems. Distributed components can operate sequentially or in parallel.

FIG. 7 depicts a flow diagram of an example method 700 of obtaining images and implementing vehicle control according to example embodiments of the present disclosure. Incoming light can be filtered (702) through one or more color filter arrays of in image capture device. The one or more color filter arrays used to filter light at (702) can include a plurality of clear filter elements and a plurality of color-sensitive filter elements, the latter of which can include at least one first color-sensitive filter element sensitive to a first band of the visible color spectrum (e.g., a red color-sensitive element) and at least one second color-sensitive filter element sensitive to a second band of the visible color spectrum different than the first band (e.g., a blue color-sensitive element). In some examples, the one or more color filter arrays used to filter light at (702) can also include at least one third color-sensitive filter element sensitive to a third band of the visible color spectrum different than the first and second bands (e.g., a green-sensitive filter element). In some examples, the one or more color filter arrays used to filter light at (702) can correspond to color filter array 106 of FIG. 1, color filter array 200 or FIG. 2, color filter array 300 of FIG. 3, color filter array 400 of FIG. 4, or other color filter arrays as described herein.

At (704), method 700 can include detecting raw image capture data at one or more image sensors. The raw image capture data detected at (704) can be indicative of an amount of incident light present at the one or more image sensors. The one or more image sensors can correspond, for example, to image sensor 108 and can include an array of image sensor elements 116 provided to receive output from filter elements 120 of one or more color filter arrays (e.g., color filter arrays 106, 200, 300, 400, etc.) In some examples, raw image capture data detected at (704) at each image sensor element 116 of image sensor 108 can be configured to receive light filtered by a corresponding filter element 120a-d of color filter array 106. In this manner, raw image capture data detected at (704) can include clear/white light at some pixels and filtered colored light at other pixels. For example, raw image capture data detected at (704) can include clear/white light at about half of a total number of image sensor elements 116 of image sensor 108 and colored light at about half of a total number of image sensor elements 116 of image sensor 108. The colored light detected at (704) can include light within at least one first band of the visible color spectrum (e.g., red light) and light within at least one second band of the visible color spectrum (e.g., blue light). In some examples, colored light detected at (704) can additionally include light within at least one third band of the visible color spectrum (e.g., green light). The type of light detected at each image sensor element 116 can be dictated by the particular type of filter element 120a-d associated with that pixel.

At (706), method 700 can include determining multiple color components for each pixel of raw image capture data using one or more image processing devices (e.g., image processors 110). The multiple color components for each pixel can be determined at (706) based at least in part on the raw image capture data detected at that pixel and from at least one additional nearby pixel. Multiple color components determined at (706) for each pixel of a digital image output 126 can indicate the intensity of different color components per pixel (e.g., a first color component, second color component, and third color component.) Multiple color component values determined at (706) for each pixel can indicate intensity levels for multiple color components using a variety of formats. In some examples, multiple color components are determined at (706) for each pixel using an RGB format including red, green and blue color components or a CMY format including cyan, magenta and yellow color components. In other examples, multiple color component values are determined at (706) for each pixel using a hex color code (#aabbcc) format including a three-byte hexadecimal number consisting of six digits, with each byte or pair of characters (aa, bb, and cc) representing the intensity of first, second and third color components in the respective pixel.

At (708), method 700 can include generating a digital image output 126. Digital image output 126 generated at (708) can be based at least in part on the multiple color components determined for each pixel at (706). Additional image processing may also be implemented as part of generating (706) the digital image output. For example, a digital image output 126 can be generated at (708) to include noise reduction at one or more pixels, which reduces various sources of optical, electrical, digital and/or power noise by averaging detected parameters across similar neighboring pixels. In some examples, a digital image output 126 can be generated at (708) to include RGB blending that converts the color space captured by image sensor 108 to a standard or reference color space. In some examples, a digital image output 126 can be generated at (708) that can include one or more image enhancements such as edge enhancement and/or contrast enhancement that can help further improve image quality for applications such as object detection and the like.

After the digital image output 126 is generated at (708), the digital image output 126 can be provided as output data at (710) from the image capture device 100. In some examples, digital image output 126 can be provided as output data at (710) from image capture device 100 to one or more other computing devices, processors or control devices. For example, digital image output 126 can be provided as output data at (710) to a vehicle control system 602 as depicted in FIG. 6. In some examples, digital image output 126 can be provided as output data at (710) for display on a display device associated with a vehicle such that a user can view one or more aspects of a vehicle's surrounding environment (e.g., surroundings near a front and/or rear bumper of a vehicle). In some examples, digital image output can be provided as output data at (710) to a vehicle control system 602 for an autonomous vehicle.

The digital image output provided at (710) can be further analyzed to identify at (712) at least one object in the digital image. The at least one object identified or detected at (712) can include one or more of a person (e.g., a pedestrian), an animal, a vehicle, a bicycle, a road, a road feature, a navigational object such as signage, a building, an object, road conditions (e.g., curves, potholes, dips, bumps, changes in grade), distances between vehicle 650 and other vehicles and/or objects, etc. In response to detection at (712) of at least one object in the digital image (or conversely, a detected absence of an object), one or more operational parameters of a vehicle can be controlled at (714). Operational parameters can include vehicle speed, direction, acceleration, deceleration, steering and/or operation of vehicle components to follow a planned motion and/or navigational course. In some examples, operational parameters can be controlled at (714) to navigate a vehicle in an autonomous or semi-autonomous operational mode.

Referring now to FIG. 8, a method (800) for processing images can include more particular features for determining multiple color components for each pixel. Raw image capture data 114 can be received at (802) from an image sensor for a plurality of pixels. For example color filter arrays 200, 300 including only first and second color-sensitive elements (e.g., red-sensitive and blue-sensitive elements) but no green-sensitive elements, method 800 can then include determining (804) a green color component for each clear pixel. In some examples, a green color component can be determined at (804) by subtracting the intensity level of detected light measured at one or more nearby blue and red pixels from the intensity level of detected light captured at each clear pixel. For example, a green color component value for each pixel corresponding to a clear filter element 210 in color filter array 200 can be determined by subtracting from the intensity of light detected at that clear pixel, an average of the blue light detected at pixels corresponding to blue-sensitive filter elements 208 and an average of the red light detected at pixels corresponding to red-sensitive filter elements 206.

Once a green color component is determined for each clear pixel at (804), each pixel can have at least one associated color component value. Pixels having blue components or red components will have been measured directly and pixels having green components will have been interpolated using the directly measured red and blue values. For example color filter arrays 400 that include red-sensitive, green-sensitive and blue-sensitive filter elements interspersed among clear filter elements, determining green color components at (804) may not be employed.

Method (800) can also include determining multiple color components at (806) for each pixel by interpolating raw image capture data from that pixel and selected nearby pixels. In some examples, multiple color components can be determined at (806) using raw image capture data from adjacent pixels. For example, pixels having a red color component can interpolate corresponding blue and green color components by consulting blue and green color components at nearby pixels. Similarly, pixels having a blue color component can interpolate corresponding green and red color components by consulting green and red color components at nearby pixels. Pixels having a green color component can interpolate corresponding red and blue color components by consulting red and blue color components at nearby pixels. Clear pixels can interpolate red, green and blue color components at that pixel by consulting red, green and blue color components at nearby pixels. In still further examples, a color component that is measured directly at a given pixel can be adjusted based on values from nearby pixels to help reduce noise, implement color blending and/or image enhancement and/or other image processing features.

In some examples, multiple color components can be determined at (806) by interpolating color component values from one or more adjacent pixels in the vertical horizontal and/or diagonal directions from a given pixel. In some examples, multiple color components can be determined at (806) by using a nearest-neighbor interpolation by which color components of adjacent pixels are copied to that pixel. In some examples, multiple color components can be determined at (806) by averaging color component values from a plurality of adjacent and/or nearby pixels. Specific averaging techniques can be implemented to determine multiple color components at (806) including but not limited to bilinear interpolation, bicubic interpolation, polynomial interpolation, spline interpolation, Lanczos resampling, or other techniques. After multiple color components are determined for each pixel at (806), the multiple color components are used to generate a digital image output at (808). Additional steps such as disclosed in FIG. 7 can then be employed relative to the digital image output generated at (808), including but not object identification at (712) and/or controlling one or more operational parameters of a vehicle at (714).

While the present subject matter has been described in detail with respect to specific example embodiments and methods thereof, it will be appreciated that those skilled in the art, upon attaining an understanding of the foregoing can readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. An image capture device, comprising:
an image sensor including an array of sensor elements configured to detect incoming light provided incident to a surface of the image sensor;
a color filter array positioned adjacent to the image sensor for filtering the incoming light provided incident to the surface of the image sensor, wherein the color filter array comprises an array of filter elements including a plurality of clear filter elements and a plurality of color-sensitive filter elements, wherein the plurality of color-sensitive filter elements comprise at least one first color-sensitive filter element sensitive to a first band of the visible color spectrum and at least one second color-sensitive filter element sensitive to a second band of the visible color spectrum different than the first band, wherein the color filter array and the image sensor collectively provide raw image capture data at a plurality of pixels corresponding to individual sensor elements and corresponding filter elements;
an image processor configured to receive the raw image capture data and determine an output value for each pixel indicating the intensity of multiple color components for the pixel, wherein the output value at each pixel is determined at least in part based on the raw image capture data at that pixel and at selected nearby pixels.

2. The image capture device of claim 1, wherein the at least one first color-sensitive filter element sensitive to a first band of the visible color spectrum comprises a red-sensitive filter element and wherein the at least one second color-sensitive filter element sensitive to a second band of the visible color spectrum comprises a blue-sensitive filter element.

3. The image capture device of claim 2, wherein the array of filter elements does not include any green-sensitive filter elements, and wherein the image processor is configured to interpolate a green color component at each pixel corresponding to a clear filter element based on red and blue components determined at one or more nearby pixels.

4. The image capture device of claim 1, wherein the plurality of color-sensitive filter elements further comprises at least one third color-sensitive filter element sensitive to a third band of the visible color spectrum different than the first band and the second band.

5. The image capture device of claim 4, wherein the at least one first color-sensitive filter element sensitive to a first band of the visible color spectrum comprises a red-sensitive filter element, wherein the at least one second color-sensitive filter element sensitive to a second band of the visible color spectrum comprises a blue-sensitive filter element, and wherein the at least one third color-sensitive filter element sensitive to a third band of the visible color spectrum comprises a green-sensitive filter element.

6. The image capture device of claim 5, wherein the array of filter elements comprises a substantially similar number of clear filter elements as color-sensitive filter elements, and a substantially similar number of red-sensitive filter elements as blue-sensitive filter elements, and wherein the number of green-sensitive filter elements is substantially similar to the total combined number of red-sensitive and blue-sensitive filter elements.

7. The image capture device of claim 5, wherein the array of filter elements comprises a number of clear filter elements, a number of red-sensitive filter elements, a number of blue-sensitive filter elements, and a number of green-sensitive filter elements that are substantially similar.

8. The image capture device of claim 1, wherein the output value for each pixel indicating the intensity of multiple color components comprises a red color component, a green color component and a blue color component.

9. The image capture device of claim 1, further comprising an infrared (IR) light source configured to enhance illumination of objects associated with the incoming light provided incident to the surface of the image sensor.

10. A color filter array for an image capture device, comprising:
a plurality of clear filter elements;
a plurality of first color-sensitive filter elements sensitive to a first band of the visible color spectrum; and
a plurality of second color-sensitive filter elements sensitive to a second band of the visible color spectrum different than the first band;
wherein the plurality of clear filter elements are interspersed among the plurality of first color-sensitive filter elements and second color-sensitive filter elements in the color filter array to provide additional white light at corresponding locations across an image sensor surface.

11. The color filter array for an image capture device of claim 10, wherein the plurality of first color-sensitive filter elements sensitive to a first band of the visible color spectrum comprises red-sensitive filter elements and wherein the plurality of second color-sensitive filter elements sensitive to a second band of the visible color spectrum comprises blue-sensitive filter elements, and wherein each clear filter element is adjacent to at least one red-sensitive filter element and at least one blue-sensitive filter element.

12. The color filter array for an image capture device of claim 10, wherein the color filter array comprises a substantially similar number of clear filter elements as color-sensitive filter elements, and a substantially similar number of first color-sensitive filter elements as second color-sensitive filter elements.

13. The color filter array for an image capture device of claim 10, wherein the color filter array comprises a plurality of 2×2 pixel blocks, each pixel block consisting of two clear filter elements at opposing corners and a first color-sensitive filter element and a second color-sensitive filter element at opposing corners.

14. The color filter array for an image capture device of claim 10, further comprising a plurality of third color-sensitive filter elements sensitive to a third band of the visible color spectrum different than the first band and the second band.

15. The color filter array for an image capture device of claim 14, wherein the plurality of first color-sensitive filter elements sensitive to a first band of the visible color spectrum comprises red-sensitive filter elements, wherein the plurality of second color-sensitive filter elements sensitive to a second band of the visible color spectrum comprises blue-sensitive filter elements, and wherein the plurality of third color-sensitive filter elements sensitive to a third band of the visible color spectrum comprises green-sensitive filter elements.

16. The color filter array for an image capture device of claim 14, wherein the color filter array comprises a plurality of 2×2 pixel blocks, each pixel block consisting of a first color-sensitive filter element, a second color-sensitive filter element, a third color-sensitive filter element and a clear filter element.

17. A method, comprising:
filtering, by one or more color filter arrays, incoming light through an array of filter elements including a plurality of clear filter elements and a plurality of color-sensitive filter elements, wherein the plurality of color-sensitive filter elements comprise at least one first color-sensitive filter element sensitive to a first band of the visible color spectrum and at least one second color-sensitive filter element sensitive to a second band of the visible color spectrum different than the first band;
detecting, by one or more image sensors, raw image capture data indicative of an amount of incident light present at an image sensor including an array of sensor elements provided to receive output from the one or more color filter arrays, the one or more color filter arrays and the one or more image sensors collectively providing raw image capture data at a plurality of pixels;
determining, by one or more processing devices, multiple color components for each pixel based at least in part on the raw image capture data at that pixel or at one or more nearby pixels;
generating, by the one or more processing devices, a digital image based on the multiple color components determined for each pixel; and
providing, by the one or more processing devices, the digital image as output data.

18. The method of claim 17, wherein detecting, by one or more image sensors, raw image capture data is implemented in accordance with a global shutter exposure protocol that exposes all sensor elements within the image sensor to incoming light at substantially the same time.

19. The method of claim 17, further comprising:
identifying, by the one or more processing devices, at least one object in the digital image provided as output; and
controlling, by the one or more processing devices, an operational parameter of a vehicle in response to identification of the at least one object in the digital image.

20. The method of claim 17, wherein:
identifying, by the one or more processing devices, at least one object comprises identifying, by the one or more processing devices, one or more of a person, a vehicle, a road or a navigational object; and
controlling, by the one or more processing devices, an operational parameter of a vehicle comprises controlling, by the one or more processing devices, at least one of a direction or a speed of the vehicle.
